(19) United States
(12) Patent Application Publication
(10) Pub. No.: US 2026/0028518 A1
(43) Pub. Date: Jan. 29, 2026

(54) LOW THERMAL IMPEDANCE PHASE CHANGE THERMAL INTERFACE MATERIALS

(71) Applicant: Honeywell International Inc., Charlotte, NC (US)

(72) Inventors: Kai Wang, Shanghai (CN); Lu Xiao, Zhangjiagang (CN); Shiming He, Zhangjiagang (CN); Qian Yang, Shanghai (CN)

(21) Appl. No.: 19/270,182

(22) Filed: Jul. 15, 2025

Related U.S. Application Data
(60) Provisional application No. 63/674,653, filed on Jul. 23, 2024.

(51) Int. Cl. C09K 5/06; C08K 3/22; C08L 47/00; H01L 23/367; H01L 23/373

(52) U.S. Cl. CPC C09K 5/063; C08K 3/22; C08L 47/00; H01L 23/3672; H01L 23/3733; C08K 2003/2296; C08K 2201/001; C08L 2203/20

(57) ABSTRACT

A phase change thermal interface material including a thermally conductive filler, a phase change wax, a coupling agent, and a polymer matrix material. The thermally conductive filler includes from about 50 wt. % to about 70 wt. % aluminum powder; from about 19 wt. % to about 30 wt. % aluminum oxide; and from about 1 wt. % to about 9 wt. % zinc oxide, based on the total weight of the phase change thermal interface material. The phase change thermal interface material has a thermal impedance from about 0.02° Ccm²/W to about 0.04° Ccm²/W, as determined by ASTM D5470.

### CROSS-REFERENCE TO RELATED APPLICATION

This application claims priority to Provisional Application No. 63/674,653, filed Jul. 23 2024, which is herein incorporated by reference in its entirety.

### FIELD

The present disclosure relates generally a low thermal impedance phase change thermal interface material (PC TIM).

### BACKGROUND

With dramatic recent increases in chip power density, there has been an increase in the desirability of higher thermal performance thermal interface materials (TIMs). Phase change materials (PCM) as one of the traditional TIMs, show excellent thermal properties and reliability compared with thermal grease. However, PCMs in the market exhibit an interface thermal resistance of above 0.04° C. cm2/W, which greatly limits the heat dissipation of high powder device. Novel TIMs, such as liquid metal and graphene, have been developed in recent years to address this problem. Although the thermal conductivity of novel TIMs achieves from tens to thousands W/mK, due to their poor wettability to the interface, the interface thermals resistance reaches 0.01˜0.03° C. cm2/W. Moreover, due to the high price and poor manufacturability of novel TIMs, the application and promotion of these materials are still a problem.

It is therefore desirable to develop a low thermal resistance phase change TIM with good manufacturability.

### SUMMARY

The present disclosure provides a phase change thermal interface material, including: a thermally conductive filler; a phase change wax; a coupling agent; a polymer matrix material; and at least one additive. The thermally conductive filler includes from about 50 wt. % to about 70 wt. % of aluminum powder; from about 19 wt. % to about 30 wt. % of aluminum oxide; and from about 1 wt. % to about 9 wt. % zinc oxide, based on the total weight of the phase change thermal interface material. The phase change thermal interface material has a thermal impedance from about 0.02° C.cm²/W to about 0.04° C.cm²/W as determined by ASTM D5470.

The present disclosure further provides an electronic component including: a heat sink; an electronic chip; and a phase change thermal interface material positioned between the heat sink and the electronic chip. Thee phase change thermal interface material includes: a thermally conductive filler; a phase change wax; a coupling agent; a polymer matrix material; and at least one additive. The thermally conductive filler includes at least one of: from about 50 wt. % to about 70 wt. % aluminum powder; from about 19 wt. to about 30 wt. % aluminum oxide; and from about 1 wt. % to about 9 wt. % zinc oxide, based on the total weight of the phase change thermal interface material. The phase change thermal interface material has a thermal impedance from about 0.02° C.cm²/W to about 0.04° C.cm²/W as determined by ASTM D5470.

The present disclosure additionally provides a method for applying a phase change thermal interface material to a substrate, including: combining each of a thermally conductive filler, a phase change wax, a coupling agent, a polymer matrix material, and an additive to form the phase change thermal interface material; combining the phase change thermal interface material with a solvent to form a phase change thermal interface material paste; and applying the phase change thermal interface material paste to a metal substrate. The thermally conductive filler includes from about 50 wt. % to about 70 wt. % aluminum powder; from about 19 wt. % to about 30 wt. % aluminum oxide; and from about 1 wt. % to about 9 wt. % zinc oxide, based on the total weight of the phase change thermal interface material.

### BRIEF DESCRIPTION OF THE DRAWINGS

The above-mentioned and other features and advantages of this disclosure, and the manner of obtaining them, will become more apparent, and will be better understood by reference to the following description of the exemplary embodiments taken in conjunction with the accompanying drawings, wherein:

FIG. 1A schematically illustrates an electronic chip, a heat spreader, a heat sink, and first and second thermal interface materials;

FIG. 1B schematically illustrates an exemplary thermal interface material positioned between an electronic chip and a heat sink;

FIG. 1C schematically illustrates an exemplary thermal interface material positioned between a heat spreader and a heat sink; and

FIG. 1D schematically illustrates an exemplary thermal interface material positioned between an electronic chip and a heat spreader.

Corresponding reference characters indicate corresponding parts throughout the several views. Although the drawings represent embodiments of various features and components according to the present disclosure, the drawings are not necessarily to scale, and certain features may be exaggerated in order to better illustrate and explain the present disclosure. The exemplification set out herein illustrates an embodiment of the invention, and such an exemplification is not to be construed as limiting the scope of the invention in any manner.

### DETAILED DESCRIPTION

The present disclosure relates to a phase change thermal interface material (PC TIM) that includes thermally conductive filler, phase change wax, a coupling agent, a polymer matrix material, and at least one additive. The PC TIM may have a low thermal impedance.

### I. Phase Change Thermal Interface Material Composition

The present disclosure relates to a phase change thermal interface material (PC TIM) with low thermal resistance compared to traditional TIMs. The PC TIM composition may comprise a thermally conductive filler, a phase change wax,

### A. Thermally Conductive Filler

The PC TIM of the present disclosure may comprise at least one thermally conductive filler. In one embodiment, the PC TIM comprises three thermally conductive fillers. The thermally conductive filler may be, for example, an aluminum powder, a solid lubricant, and zinc oxide.

The PC TIM may comprise a total weight percent of thermally conductive filler, for example, from about 84 wt. %, about 86 wt. %, about 88 wt. % to about 90 wt. %, about 92 wt. %, about 94 wt. %, or within any range using any two of the foregoing as endpoints, such as 84 wt. %. to 94 wt. %, 86 wt. % to 92 wt. %, or 88 wt. % to 90 wt. %, based on the total weight of the PC TIM composition.

The PC TIM composition may comprise a total volume percent of thermally conductive filler, for example, from about 78 vol. %, about 79 vol. %, about 80 vol. % to about 81 vol. %, about 82 vol. %, about 83 vol. % or within any range using any two of the foregoing as endpoints, such as 78 vol. %. to 83 vol. %, 79 vol. % to 82 vol. %, or 80 vol. % to 81 vol. %, based on the total volume of the PC TIM composition.

i. Aluminum Powder

The thermally conductive filler may comprise an aluminum powder. The aluminum powder may have an average particle size (D50) from about 1 μm, about 2 μm, about 3 μm to about 4 μm, about 5 μm, about 6 μm, or any range using any of the foregoing values as endpoints, such as 1 μm to 6 μm, 2 μm to 5 μm, or 4 μm to 3 μm, as determined by dynamic light scattering ISO 13320-1.

The PC TIM may comprise a weight percent of aluminum powder, for example, from about 50 wt. %, about 55 wt. %, about 60 wt. % to about 63 wt. %, about 67 wt. %, about 70 wt. %, or within any range using any two of the foregoing as endpoints, such as 50 wt. % to 70 wt. %, 55 wt. % to 67 wt. %, or 60 wt. % to 63 wt. %, based on the total weight of the PC TIM.

The PC TIM may comprise a weight percent of aluminum powder, for example, from about 52 vol. %, about 58 vol. %, about 60 vol. % to about 62 vol. %, about 64 vol. %, about 68 vol. % or within any range using any two of the foregoing as endpoints, such as 52 vol. %. to 68 vol. %, 58 vol. % to 64 vol. %, or 60 vol. % to 62 vol. %, based on the total volume of the PC TIM.

ii. Solid Lubricant

The thermally conductive filler may comprise a solid lubricant, such as aluminum oxide (Al₂O₃). The solid filler may reduce sharp increases in viscosity during formulation of the PC TIM. The solid lubricant may be a high-purity spherical alumina powder, which is manufactured by combustion method, plasma method, or any other suitable manufacturing method.

The powder may have a high sphericity, non-porous surface, and excellent dispersibility. In one example, a solid lubricant with an average particle size (D50) of less than 1 m, less than 0.5 m, less than 0.4 m, less than 0.3 m, less than 0.2 m, as determined by dynamic light scattering ISO 13320-1, may be used, with which, the viscosity of PC TIM may be reduced from above 1500 Pa·s to below 1000 Pa·s.

The particle size of the solid lubricant may be smaller than the particle size of the aluminum powder to achieve a close packing effect. In one example, the particle size of the aluminum powder is 5 μm and the particle size of the solid lubricant is 0.4 μm. In another example, the particle size of the aluminum powder is 3 μm and the particle size of the solid lubricant is 0.2 μm.

The PC TIM may comprise a weight percent of solid lubricant, for example, from about 19 wt. %, about 21 wt. %, about 23 wt. % to about 25 wt. %, about 27 wt. %, about 30 wt. %, or within any range using any two of the foregoing as endpoints, such as 19 wt. %. to 30 wt. %, 21 wt. % to 27 wt. %, or 23 wt. % to 25 wt. %, based on the total weight of the PC TIM.

The PC TIM may comprise a weight percent of solid lubricant, for example, from about 12 vol. %, about 14 vol. %, about 16 vol. % to about 18 vol. %, about 20 vol. %, about 24 vol. % or within any range using any two of the foregoing as endpoints, such as 12 vol. %. to 24 vol. %, 14 vol. % to 20 vol. %, or 16 vol. % to 18 vol. %, based on the total volume of the PC TIM.

iii. Zinc Oxide

The thermally conductive filler may comprise zinc oxide (ZnO). Zinc oxide may soften the composition of the PC TIM.

The PC TIM may comprise a weight percent of zinc oxide, for example, from about 1 wt. %, about 2 wt. %, about 4 wt. % to about 6 wt. %, about 7 wt. %, about 9 wt. %, or within any range using any two of the foregoing as endpoints, such as 1 wt. %. to 9 wt. %, 2 wt. % to 7 wt. %, or 4 wt. % to 6 wt. %, based on the total weight of the PC TIM.

The PC TIM may comprise a weight percent of zinc oxide, for example, from about 0.5 vol. %, about 1.5 vol. %, about 2 vol. % to about 2.5 vol. %, about 3 vol. %, about 4.0 vol. % or within any range using any two of the foregoing as endpoints, such as 0.5 vol. %. to 4.0 vol. %, 1.5 vol. % to 3 vol. %, or 2 vol. % to 2.5 vol. %, based on the total volume of the PC TIM.

### B. Phase Change Wax

In some exemplary embodiments, the PC TIM comprises one or more phase change waxes (PC waxes). A phase change wax is a wax having a melting point or melting point range at or below the operating temperature of a portion of an electronic device in which the PC TIM is to be used. An exemplary phase change wax may be paraffin wax or polymer wax. Paraffin waxes are a mixture of solid hydrocarbons having the general formula CₙH₂ₙ₊₂ and having melting points in the range from about 200° C. to about 100° C. Polymer waxes include polyethylene waxes and polypropylene waxes, and typically have a range of melting points from about 400° C. to 160° C.

In some embodiments, the amount of phase change wax can be used to can adjust the hardness of the PC TIM. For example, in some embodiments wherein the loading of the phase change wax is low, the PC TIM composition may be in the form of a soft gel, and in some embodiments wherein the loading of the phase change wax is high, the PC TIM composition may be a hard solid. The PC TIM may comprise a weight percent of the one or more phase change waxes in an amount, for example, from about 0.1 wt. %, about 0.5 wt. %, about 1.0 wt. % to about 2.0 wt. %, about 3.0 wt. %, about 5.0 wt. %, or any ranges using any of the foregoing values as endpoints, such as 0.1 wt. % to 5.0 wt. %, 0.5 wt. % to 3.0 wt. %, 1.0 wt. % to 2.0 wt. %, based on the total weight of the PC TIM.

The PC TIM may comprise a volume percent of the one or more phase change waxes in an amount, for example, from about 0.25 vol. %, about 0.75 vol. %, about 1.00 vol. % to about 1.25 vol. %, about 1.75 vol. %, about 2.10 vol. %, or any ranges using any of the foregoing values as endpoints, such as 0.25 vol. % to 2.10 vol. %, 0.75 vol. % to 1.75 vol. %, 1.00 vol. % to 1.25 vol. %, based on the total volume of the PC TIM.

### C. Coupling Agent

The PC TIM provided by the present disclosure may comprise one or more coupling agents. Inclusion of a coupling agent may improve thermal properties, such as properties at relatively high temperatures.

The coupling agent may be selected one or several types from silane coupling agents, titanate coupling agents, aluminate coupling agent, zirconate coupling agent and stearic acid coupling agent.

In one example, the coupling agent is titanium IV 2,2 (bis 2-propenolatomethyl) butanolato, tris(dioctyl)pyrophosphato-O. Preferred titanate coupling agents include: titanium IV 2,2 (bis 2-propenolatomethyl)butanolato, tris(dioctyl)pyrophosphato-O; zirconium IV 2,2 (bis 2-propenolatomethyl)butanolato, tris(diisooctyl)pyrophosphato-O; titanium IV 2-propanolato, tris(dioctyl)-pyrophosphato-O) adduct with 1 mole of diisooctyl phosphite; titanium IV bis(dioctyl)pyrophosphato-O, oxoethylenediolato, (Adduct), bis(dioctyl) (hydrogen)phosphite-O; titanium IV bis(dioctyl)pyrophosphato-O, ethylenediolato (adduct), bis(dioctyl)hydrogen phosphite; and zirconium IV 2,2-bis(2-propenolatomethyl) butanolato, cyclo di[2,2 (bis 2-propenolatomethyl) butanolato], pyrophosphato-O,0.

The coupling agent may increase the dispersion and wettability of the PC TIM composition.

The PC TIM composition may comprise a weight percent of one or more coupling agents, for example, from about 0.3 wt. %, about 0.5 wt. %, about 1.0 wt. % to about 1.3 wt. %, about 1.5 wt. %, about 2.0 wt. % or within any range using any two of the foregoing as endpoints, such as from 0.3 wt. %. to 2.0 wt. %, 0.5 wt. % to 1.5 wt. %, or 1.0 wt. % to 1.3 wt. %, based on the total weight of the PC TIM composition.

The PC TIM composition may comprise a volume percent of one or more coupling agents, for example, from about 0.75 vol. %, about 1.00 vol. %, about 1.25 vol. % to about 1.50 vol. %, about 1.75 vol. %, about 2.10 vol. %, or within any range using any two of the foregoing as endpoints, where vol. % is based on the total weight of the PC TIM composition, such as from 0.75 vol. %. to 2.10 vol. %, 1.00 vol. % to 1.75 vol. %, or 1.25 vol. % to 1.50 vol. %, based on the total volume of the PC TIM composition.

### D. Polymer Matrix Material

The PC TIM may comprise a polymer matrix material. The polymer matrix material may provide a matrix for incorporating the thermally conductive fillers and provide flowability when pressed under heat and pressure.

The polymer matrix material may comprise a hydrocarbon rubber compound or a blend of rubber compounds. In one embodiment, the polymer matrix is a hydrogenated polybutadiene monool. Further exemplary materials include saturated and unsaturated rubber compounds. In some embodiments, saturated rubbers may be less sensitive to thermal oxidation degradation than unsaturated rubber compounds. Exemplary saturated rubber compounds include ethylene-propylene rubbers (EPR, EPDM), polyethylene/butylene, polyethylene-butylene-styrene, polyethylene-propylene-styrene, hydrogenated polyalkyldiene “mono-ols” (such as hydrogenated polybutadiene mono-ol, hydrogenated polypropadiene mono-ol, hydrogenated polypentadiene mono-ol), hydrogenated polyalkyldiene “diols” (such as hydrogenated polybutadiene dial, hydrogenated polypropadiene diol, hydrogenated polypentadiene diol) and hydrogenated polyisoprene, polyolefin elastomer, or any other suitable saturated rubber, or blends thereof. In one embodiment, the polymer matrix material is a hydrogenated polybutadiene mono-ol, which may also be referred to as a hydroxyl-terminated ethylene butylene copolymer, specialty mono-ol.

In one exemplary embodiment, the polymeric matrix material comprises a silicone rubber, a siloxane rubber, a siloxane copolymer or any other suitable silicone-containing rubber.

The PC TIM composition provided by the present disclosure may comprise a weight percent a polymer matrix material, for example, from about 5.0 wt. %, about 5.5 wt. %, about 6.0 wt. % to about 7.0 wt. %, about 8.0 wt. %, about 10.0 wt. % or within any range using any two of the foregoing as endpoints, such as from 5.0 wt. %. to 10.0 wt. %, 5.5 wt. % to 8.0 wt. %, or 6.0 wt. % to 7.0 wt. %, based on the total weight of the PC TIM composition.

The PC TIM composition may comprise a volume percent of a polymer matrix material, for example, from about 13.0 vol. %, about 14.0 vol. %, about 15.0 vol. % to about 16.0 vol. %, about 17.0 vol. %, about 18.2 vol. % or within any range using any two of the foregoing as endpoints, such as from 13.0 vol. %. to 18.2 vol. %, 14.0 vol. % to 17.0 vol. %, or 15.0 vol. % to 16.0 vol. %, based on the total volume of the PC TIM composition.

### E. Additives

The PC TIM may comprise at least one additive to enhance the physical properties. The at least one additive may include antioxidants, dispersants, crosslinkers, catalysts, inhibitors, release agents, pigments, and any combination thereof.

The PC TIM composition provided by the present disclosure may comprise a weight percent of one or more additives, for example, from about 0.05 wt. %, about 0.1 wt. %, about 0.5 wt. % to about 0.6 wt. %, about 0.8 wt. %, about 1.0 wt. % or within any range using any two of the foregoing as endpoints, such as from 0.05 wt. %. to 1.0 wt. %, 0.1 wt. % to 0.8 wt. %, or 0.5 wt. % to 0.6 wt. %, based on the total weight of the PC TIM composition.

The PC TIM composition may comprise a volume percent of one or more additive, for example, from about 0.70 vol. %, about 1.00 vol. %, about 1.25 vol. % to about 1.50 vol. %, about 1.75 vol. %, about 2.10 vol. % or within any range using any two of the foregoing as endpoints, such as from 0.70 vol. %. to 2.10 vol. %, 1.00 vol. % to 1.75 vol. %, or 1.25 vol. % to 1.50 vol. %, based on the total volume of the PC TIM composition.

i. Antioxidants

An antioxidant may inhibit thermal degradation of the polymer matrix by transferring elections of a free radical to an oxidizing agent. Exemplary antioxidants may include phenolic-type antioxidants, amine-type antioxidants, or any other suitable type of antioxidant or combinations thereof, such as a sterically hindered phenol or amine type antioxidant. Exemplary antioxidants include phenol type antioxidants such as Irganox® 1076, or octadecyl 3-(3,5-di-(tert)-butyl-4-hydroxyphenyl) propionate; amine type antioxidants such as Irganox® 565, or 2,6-di-tert-butyl-4-(4,6-bis(octylthio)-1,3,5-triazin-2-ylamino) phenol, and sulfur containing phenolic antioxidants, such as a sterically hindered sulfur containing phenolic antioxidant. Other exemplary antioxidants may include Irganox® 1010, Irgafox® 168, and Irganox® 802.

ii. Crosslinkers

The PC TIM may comprise one or more crosslinkers, such as amine or amine-based resins. Crosslinkers may be added or incorporated into the PC TIM composition to facilitate a crosslinking reaction between the crosslinker and the primary or terminal hydroxyl groups on at least one of the polymer matrix materials.

Exemplary crosslinkers may include an amine or amine-based resin that comprises at least one amine substituent group on any part of the resin backbone. Exemplary amine and amine-based resins include alkylated melamine resins and synthetic resins derived from the reaction of urea, thiourea, melamine or allied compounds with aldehydes, particularly formaldehyde. In a more particular embodiment, the crosslinker may be a resin selected from the group consisting of primary amine resins, secondary amine resins, tertiary amine resins, glycidyl amine epoxy resins, alkoxybenzyl amine resins, epoxy amine resins, melamine resins, alkylated melamine resins, and melamine-acrylic resins.

In one exemplary embodiment, the crosslinker may be a melamine resin, such as an alkylated melamine resin, or even more particularly a butylated melamine resin. Melamine resins are ring-based compounds, whereby the ring contains three carbon and three nitrogen atoms. Melamine resins typically combine easily with other compounds and molecules through condensation reactions. Melamine resins typically can react with other molecules and compounds to facilitate chain growth and crosslinking, are more water resistant and heat resistant than urea resins, can be used as water-soluble syrups or as insoluble powders dispersible in water, and have high melting points (greater than 325° C.) and are relatively non-flammable). Alkylated melamine resins, such as butylated melamine resins, are formed by incorporating alkyl alcohols during the resin formation. They are soluble in paint and enamel solvents and in surface coatings.

iii. Ion Scavengers

The PC TIM may comprise one or more ion scavengers. Without wishing to be bound by any theory, it is believed that the addition of an ion scavenger inhibits metal ion-induced free radical formation. The ion scavenger is believed to capture and bind metal ions in a complex such that the metal ions no longer have an empty electron orbit and are effectively disabled from initiation the formation of free radicals in the polymer.

Exemplary ion scavengers include nitrogen containing complexing agents, phosphorous containing complexing agents, and hydroxyl carboxylic acid based complexing agents. In some exemplary embodiments, the ion scavenger is selected from acid amide compounds, such as hydrazide or dihydrazide. In some exemplary embodiments, the ion scavenger is selected from triazole compounds, tetrazole compounds, triazene compounds, oxamide compounds, or malonamide compounds. In some exemplary embodiments, the ion scavenger is selected from decamethylenedicarboxylic acid disalicyloylhydrazide; 3-(N-salicyloyl)amino-1,2,4-triazole; and 2′, 3-bis[[3-[3,5-di-tert-butyl-4-hydroxyphenyl]propionic]]propionyl hydrazide.

### II. Properties of the PC TIM

### A. Thermal Conductivity

The thermal conductivity of a material describes the rate at which heat is transferred by conduction through a unit cross-section area of a material. Thermal interface material is used to conduct heat away from electrical components to a heat spreader. This allows for an electrical component to avoid overheating or damaging due to heat during use.

The PC TIM of the present disclosure may exhibit relatively high thermal conductivity. For example, the PC TIM may have a thermal conductivity, for example, from about 3.5 W/(m·K), about 4.0 W/(m·K), about 4.5 W/(m·K) to about 5.0 W/(m·K), about 5.2 W/(m·K), about 5.5 W/(m·K), or within any range using any two of the foregoing as endpoints, as determined per ASTM D5470. For example, the thermal conductivity of the PC TIM may be between 3.5 W/(m·K) to 5.5 W/(m·K), 4.0 W/(m·K) to 5.2 W/(m·K), and 4.5 W/(m·K) 5.0 W/(m·K), as determined per ASTM D5470.

### B. Thermal Impedance

Thermal impedance (TI) testing characterizes the ability of a composition to diffuse heat from one electrical component to the remainder of the electrical device. The PC TIM provided by the present disclosure may have a TI, for example, from about 0.02° C.cm²/W to about 0.04° C.cm²/W as determined per ASTM D5470.

### C. Bond Line Thickness (BLT)

The final thickness of the applied PC TIM is referred to as the bond line thickness (BLT). The value of the BLT is determined, in part, by the flowability of the PC TIM when being heated by a heat generating component. BLT is related to thermal impedance (TI) and thermal conductivity (TC) by the formula TI=BLT/TC, such that lower BLT results in lower thermal impedance at the same thermal conductivity. Without wishing to be bound by any particular theory, it is believed that including multiple sizes of thermally conductive fillers allows smaller particle sizes to fill gaps present between larger particle sizes, increasing the flowability of the PC TIM and reducing the BLT. TIM formulations having low BLT tend to have low thermal impedance.

BLT is measured by sandwiching a 0.2 mm PC TIM pad between two metal plates with an area of 1 mm². External force of 35 psi is applied to the sandwiched sample. The sample is heated to 80° C. for 30 minutes. The thickness of the sandwich structure is then measured. The BLT value is obtained by subtracting the thickness of the metal plates from that of the sandwich structure following the force and heat.

The PC TIM may have a BLT, for example, from about 5 μm, about 7 μm, about 9 μm to about 11 μm, about 13 μm, about 15 μm, or any range using any of the foregoing values as endpoints, such as 5 μm to 15 μm, 7 am to 13 μm, or 9 μm to 11 μm.

### D. Viscosity

The viscosity is measured according to ASTM D3236 standard method implemented as follows. The measurement is conducted using a HAAKE Viscosity iQ instrument. Solid PC TIM is placed on the rheometer sample stage and heated to 80° C. Using the rotor test head with a diameter of 25 mm, the sample is pressed down to a thickness of 1 mm. The program settings are as follows: forward scan (120 seconds) with shear rate from 1-10/s, hold at 10/s for 60 seconds, and then backward scan (120 seconds) from 10-1/s. The viscosity of the PC TIM sample is calculated to be the average value of the holding stage.

The PC TIM may have a viscosity at 80° C. from about 500 Pa·s, about 800 Pa·s, about 1000 Pa·s to about 1200 Pa·s, about 1400 Pa·s, about 1800 Pa·s, or any range using any of the foregoing values as endpoints, such as 500 to 1800 Pa·s, 800 to 1400 Pa·s, or 1000 to 1200 Pa·s, as measured according to ASTM D3236.

### III. Applications Utilizing the PC TIM

The phase change thermal interface material composition provided by the present disclosure may be used as the thermal interface material in a variety of electronic components contexts.

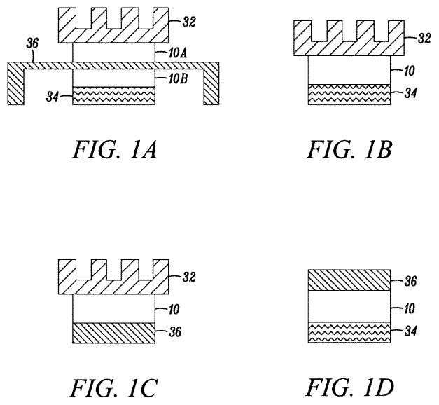

For example, FIG. 1A schematically illustrates an electronic chip 34, a heat spreader 36, and a heat sink 32 with a first thermal interface material (TIM) 10A connecting the heat sink 32 and heat spreader 36, and a second thermal interface material 10B connecting the heat spreader 36 and electronic chip 34. One or both of thermal interface materials 10A and/or 10B may be a comprise the PC TIM composition described previously. FIG. 1B illustrates the exemplary thermal interface material 10 as a thermal interface layer designated as a TIM positioned between an electronic chip 34 and a heat sink 32, such that a first surface of TIM 10 is in contact with a surface of electronic chip 34 and a second surface of TIM 1 is in contact with a surface of heat sink 32. As with FIG. 1A, TIM 10 can comprise the PC TIM composition described previously. FIG. 1C illustrates the exemplary thermal interface material 10 as thermal interface material positioned between a heat spreader 36 and a heat sink 32, such that a first surface of TIM 10 is in contact with a surface of heat spreader 36 and a second surface of TIM 10 is in contact with a surface of heat sink 32. As with FIGS. 1A and 1B, TIM 10 can comprise the PC TIM composition described previously. FIG. 1D illustrates an exemplary thermal interface material 10 as a thermal interface material positioned between an electronic chip 34 and a heat spreader 36 such that a first surface of TIM 10 is in contact with a surface of electronic chip 34 and a second surface of TIM 10 is in contact with a surface of heat spreader 36. As with FIGS. 1A, 1B and 1C, TIM 10 can comprise the 1 PC TIM composition described previously.

The PC TIM of the present disclosure may be applied to a substrate using a variety of printing processes including a roller, pressing, and a stencil printing process.

Before application to a substrate, the PC TIM may be formulated into a paste by adding solvents. Suitable solvents used to make the PC TIM paste may include toluene, xylene, p-xylene, m-xylene, mesitylene, solvent naphtha H, solvent naphtha A, Isopar H and other paraffin oils and isoparaflinic fluids, alkanes, such as pentane, hexane, isohexane, heptane, nonane, octane, dodecane, 2-methylbutane, hexadecane, tridecane, pentadecane, cyclopentane, 2,2,4-trimethylpentane, petroleum ethers, halogenated hydrocarbons, such as chlorinated hydrocarbons, nitrated hydrocarbons, benzene, 1,2-dimethylbenzene, 1,2,4-trimethylbenzene, mineral spirits, kerosene, isobutylbenzene, methylnaphthalene, ethyltoluene, ligroin, and combinations thereof.

Once the paste is formed, the paste may be printed onto a substrate, such as a nickel coated copper substrate or a nickel coated aluminum substrate, by roller, pressing the paste, or by a squeegee and stencil proces.

In one embodiment, the PC TIM paste is applied to a substrate via the stencil process. Using a stencil can offer higher controllability and/or efficiency of the application of the PC TIM to electrical components. For example, by using a stencil, the PC TIM can be applied repeatedly in the same pattern on many components. Stencils can be made in a variety of shapes, allowing the PC TIM to be applied to a variety of electrical components. The top portion of the substrate may be overlain with a stencil, where the stencil comprises both a thickness (t) and a plurality of openings arranged as a mesh. The openings may be based upon a variety of geometries, including a hexagonal geometry, whereas each opening geometry comprises a length (1) (or diameter). A distance (a) between each of the openings about the mesh may be based upon the thickness (t) of the stencil, where the distance (a) is proportional to the (t). For example, in the case where the stencil comprises a relatively large thickness (t), the distance (a) between openings may be relatively large, or conversely, when the thickness (t) is relatively small, the distance (a) between openings also may be relatively small. The distance (a) between openings may also be proportional to the length of the opening (1), such that with larger length (1) vales, the distance between opening (a) may also relatively large. Each of the at least the variable (a), (1) and (t) may be adjusted, either alone or in combination, such that a desired thickness of the PC TIM paste is deposited onto the coated metal substrate at a desired thickness.

For example, a pattern is cut in a steel substrate using a laser or other process that results in a clean edge on the stencil geometry. Some processes such as traditional steel stamping may be avoided as they could leave a rolled edge or sharp feature that may cause the stencil not to sit flush or cause scratches in the heatsink surface. The feature size of the stencil may be small enough that the straightness of the scraper edge avoids influencing the thickness of the paste (i.e., wide openings should be avoided). A honeycomb pattern may be used n as it gives an even distribution and can easily be specified on a drawing using two dimensions. A scraper can be used to press the paste into the stencil features, and the use of a pattern enables the scraper to remain parallel to the heatsink at all points. The pattern remains on the surface until the module has been pressed down and temperature cycled, at which point, the paste flows to fill voids. The shape, size, and spacing of the holes along with the thickness of the stencil determine how thick the resulting paste is once the module is mounted.

For example, when the length of the pattern (e.g., in a honeycomb orientation) cut into the steel plate is 2.0 mm, and the space between the individual pattern cutouts is 0.5 mm, the thickness of the resulting past may be approximately 0.08 mm. In another example, when the length of the honeycomb pattern is 3.0 mm, and the space between the individual pattern cutouts is 0.75 mm, the thickness of the resulting past may be approximately 0.1 mm. In still further examples, when the length of the honeycomb pattern is 4.0 mm, and the space between the individual pattern cutouts is either 1 mm or 2 mm, the thickness of the resulting past may be approximately 0.12 mm and in a range from 0.15 mm to 0.2 mm, respectively.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practices in the art to which this invention pertains.

### EXAMPLES

### Example 1: Comparative and Inventive Thermally Conductive Filler Compositions

Comparative thermally conductive filler composition examples were prepared according to the formulations in Table 1.

TABLE 1
Comparative Thermally Conductive
Filler Compositions (Ex. 1CF-9CF)

| | Conductive Filler | | | | | |
|---|---|---|---|---|---|---|
| | Al | | Solid lubricant (Al₂O₃) | | ZnO | |
| Sample | Wt. % | Vol. % | Wt. % | Vol. % | Wt. % | Vol. % |
| 1CF | 65.8 | 61.1 | 26.2 | 18.7 | 0 | 0 |
| 2CF | 55.4 | 55 | 24.0 | 18.4 | 13.1 | 6.3 |
| 3CF | 56.3 | 56.8 | 22.0 | 17.1 | 14.8 | 7.2 |
| 4CF | 68.8 | 63.2 | 22.9 | 16.3 | 0 | 0 |
| 5CF | 61.8 | 59.1 | 26.2 | 19.3 | 4.4 | 2.0 |
| 6CF | 61.4 | 58.8 | 26.6 | 19.7 | 4.5 | 2.1 |
| 7CF | 58.0 | 57.2 | 24.9 | 18.9 | 10.0 | 4.8 |
| 8CF | 86.5 | 70.4 | 0 | 0 | 0 | 0 |
| 9CF | 46.3 | 52.3 | 0 | 0 | 46.3 | 25.2 |

Inventive thermally conductive filler composition examples were prepared according to the formulations in Table 2.

TABLE 2
Inventive Thermally Conductive Filler
Compositions (Ex. 1IF-10IF)

| | Thermally Conductive Filler | | | | | |
|---|---|---|---|---|---|---|
| | Al | | Solid lubricant (Al₂O₃) | | ZnO | |
| Sample | Wt. % | Vol. % | Wt. % | Vol. % | Wt. % | Vol. % |
| 1IF | 62.73 | 59.77 | 24.94 | 18.33 | 4.64 | 2.13 |
| 2IF | 66.52 | 62.95 | 20.62 | 15.06 | 5.18 | 2.36 |
| 3IF | 63.95 | 61.26 | 22.16 | 16.37 | 6.39 | 2.95 |
| 4IF | 65.56 | 61.89 | 21.86 | 15.92 | 4.71 | 2.14 |
| 5IF | 61.70 | 59.19 | 26.47 | 19.58 | 4.43 | 2.05 |
| 6IF | 63.95 | 61.60 | 25.08 | 18.64 | 4.11 | 1.91 |
| 7IF | 62.81 | 59.40 | 26.94 | 19.65 | 2.49 | 1.14 |
| 8IF | 59.56 | 57.96 | 25.55 | 19.18 | 7.54 | 3.54 |
| 9IF | 61.48 | 58.76 | 26.39 | 19.46 | 4.50 | 2.07 |
| 10IF | 62.79 | 59.76 | 24.96 | 18.33 | 4.53 | 2.08 |

### Example 2: Comparative and Inventive PC TIM Compositions

The PC TIM compositions (comparative and inventive) were prepared by mixing the polymer, additives, PC wax, and coupling agent in a twin-planet mixer in sequent according to the proportion in the formula. The mixture was stirred until a uniform matter formed. The aluminum powder and solid lubricant was added into the pre-dispersed matrix in three parts based on the total weight and blend until the fillers were completely wetted. The zinc oxide was added into chamber and blended until a well-dispersed composite formed. The mixing process was carried out between 120˜170° C. with a blending speed of 10-100 revolutions per minute due to different viscosities.

The PC TIM was cooled and then pressed into a pad with a thickness of 0.1 mm to 0.5 mm. PC TIM may also form be formed into a paste type material. A certain amount of solvent was added to make a high viscous fluid at room temperature, which can be used to form thin film by printing method.

Comparative PC TIM composition examples were prepared according to the formulations in Table 3.

TABLE 3
Comparative PC TIM Compositions (Comp. Ex. 1-9)

| | | | | | Coupling | | | | | | |
|---|---|---|---|---|---|---|---|---|---|---|---|
| Comp. | Polymer | | PC Wax | | Agent | | Filler | Total Filler | | Additives | |
| Ex. | Wt. % | Vol. % | Wt. % | Vol. % | Wt. % | Vol. % | # | Wt. % | Vol. % | Wt. % | Vol. % |
| 1 | 6.65 | 16.68 | 0.23 | 0.57 | 0.65 | 1.63 | 1CF | 91.94 | 79.80 | 0.53 | 1.33 |
| 2 | 6.27 | 16.81 | 0.22 | 0.58 | 0.61 | 1.64 | 2CF | 92.41 | 79.64 | 0.50 | 1.34 |
| 3 | 5.74 | 15.62 | 0.20 | 0.54 | 0.56 | 1.52 | 3CF | 93.05 | 81.07 | 0.46 | 1.24 |
| 4 | 6.76 | 16.77 | 0.27 | 0.67 | 0.69 | 1.71 | 4CF | 91.74 | 79.51 | 0.54 | 1.34 |
| 5 | 5.90 | 15.22 | 0.23 | 0.60 | 0.61 | 1.57 | 5CF | 92.44 | 80.48 | 0.83 | 2.13 |
| 6 | 6.44 | 16.65 | 0 | 0 | 0.61 | 1.57 | 6CF | 92.47 | 80.54 | 0.48 | 1.24 |
| 7 | 5.90 | 15.72 | 0.19 | 0.52 | 0.58 | 1.54 | 7CF | 92.84 | 80.92 | 0.49 | 1.30 |
| 8 | 8.70 | 19.11 | 2.50 | 5.49 | 1.50 | 3.29 | 8CF | 86.50 | 70.35 | 0.80 | 1.76 |
| 9 | 6.07 | 18.50 | 0.20 | 0.61 | 0.62 | 1.89 | 9CF | 92.60 | 77.45 | 0.51 | 1.55 |

Inventive PC TIM composition examples were prepared according to the formulations in Table 4.

TABLE 4
Inventive PC TIM Compositions (Inv. Ex. 1-10)

| | | | | | Coupling | | | | | | |
|---|---|---|---|---|---|---|---|---|---|---|---|
| Inv. | Polymer | | PC Wax | | Agent | | | Total Filler | | Additives | |
| Ex. | Wt. % | Vol. % | Wt. % | Vol. % | Wt. % | Vol. % | Filler # | Wt. % | Vol. % | Wt. % | Vol. % |
| 1 | 6.35 | 16.32 | 0.22 | 0.56 | 0.62 | 1.59 | 1IF | 92.31 | 80.23 | 0.51 | 1.30 |
| 2 | 6.35 | 16.23 | 0.21 | 0.54 | 0.62 | 1.58 | 2IF | 92.32 | 80.37 | 0.50 | 1.28 |
| 3 | 6.18 | 15.97 | 0.22 | 0.57 | 0.62 | 1.61 | 3IF | 92.49 | 80.58 | 0.49 | 1.26 |
| 4 | 6.44 | 16.41 | 0.26 | 0.65 | 0.66 | 1.67 | 4IF | 92.13 | 79.95 | 0.52 | 1.31 |
| 5 | 6.06 | 15.70 | 0.24 | 0.63 | 0.62 | 1.60 | 5IF | 92.60 | 80.82 | 0.48 | 1.25 |
| 6 | 5.62 | 14.61 | 0.22 | 0.58 | 0.57 | 1.49 | 6IF | 93.14 | 82.15 | 0.45 | 1.17 |
| 7 | 6.39 | 16.32 | 0.21 | 0.54 | 0.63 | 1.60 | 7IF | 92.24 | 80.19 | 0.53 | 1.35 |
| 8 | 6.06 | 15.92 | 0.2 | 0.52 | 0.60 | 1.56 | 8IF | 92.64 | 80.67 | 0.50 | 1.32 |
| 9 | 6.03 | 15.57 | 0.24 | 0.61 | 0.64 | 1.65 | 9IF | 92.36 | 80.29 | 0.73 | 1.87 |
| 10 | 6.08 | 15.61 | 0.27 | 0.68 | 0.63 | 1.62 | 10IF | 92.28 | 80.16 | 0.75 | 1.92 |

### Example 3: Comparative and Inventive PC TIM Properties

The comparative and inventive PC TIM compositions were applied to an electronic component and tested to determine their physical properties, as shown in Table 5.

TABLE 5
Comparative and Inventive PC TIM Properties

| | Property | | | |
|---|---|---|---|---|
| | Thermal | | Thermal | |
| | Impedance | BLT | Conductivity | Viscosity |
| Sample | (° C. cm²/W) | (μm) | (W/m · K) | (Pa · s) |
| Comp. Ex. 1 | 0.044 | 10.0 | 5.5 | 920 |
| Comp. Ex. 2 | 0.050 | 12.5 | 4.9 | 1350 |
| Comp. Ex. 3 | 0.048 | 13.0 | 5.4 | 1380 |
| Comp. Ex. 4 | 0.044 | 10.0 | 4.8 | 870 |
| Comp. Ex. 5 | 0.048 | 12.0 | 5.2 | 980 |
| Comp. Ex. 6 | 0.046 | 12.6 | 5.3 | 1020 |
| Comp. Ex. 7 | 0.048 | 12.0 | 5.0 | 1230 |
| Comp. Ex. 8 | 0.083 | 10.0 | 3.8 | 650 |
| Comp. Ex. 9 | 0.102 | 15.5 | 3.1 | 1580 |
| Inv. Ex. 1 | 0.034 | 10.6 | 5.1 | 750 |
| Inv. Ex. 2 | 0.040 | 8.5 | 5.3 | 800 |
| Inv. Ex. 3 | 0.039 | 8.5 | 5.4 | 810 |
| Inv. Ex. 4 | 0.034 | 10.6 | 5.0 | 600 |
| Inv. Ex. 5 | 0.026 | 10.6 | 5.3 | 650 |
| Inv. Ex. 6 | 0.033 | 8.7 | 5.5 | 850 |
| Inv. Ex. 7 | 0.038 | 10.6 | 5.1 | 810 |
| Inv. Ex. 8 | 0.040 | 10.6 | 5.2 | 880 |
| Inv. Ex. 9 | 0.036 | 8.9 | 5.0 | 730 |
| Inv. Ex. 10 | 0.034 | 9.6 | 5.3 | 680 |

### ASPECTS

Aspect 1 is a phase change thermal interface material, comprising: a thermally conductive filler; wherein the thermally conductive filler comprises: from about 50 wt. % to about 70 wt. % of aluminum powder; from about 19 wt. % to about 30 wt. % of aluminum oxide; and from about 1 wt. % to about 9 wt. % zinc oxide, based on the total weight of the phase change thermal interface material; a phase change wax; a coupling agent; and a polymer matrix material; wherein the phase change thermal interface material has a thermal impedance from about 0.02° C.cm²/W to about 0.04° C.cm²/W, as determined by ASTM D5470.

Aspect 2 is the phase change thermal interface material of Aspect 1, wherein the thermally conductive filler further comprises from about 52 vol. % to 68 vol. % of aluminum powder; from about 12 vol. % to about 24 vol. % of aluminum oxide; and from about 0.5 vol. % to about 4 vol. % zinc oxide, based on the total volume of the phase change thermal interface material.

Aspect 3 is the phase change thermal interface material of either Aspect 1 or Aspect 2, wherein the phase change thermal interface material has a thermal conductivity from about 3.5 W/m·K to about 5.5 W/m·K, as determined by ASTM D5470.

Aspect 4 is the phase change thermal interface material of any one of Aspect 1-3, wherein the phase change thermal interface material has a viscosity from about 500 Pa·s to about 1800 Pa·s at 80° C.

Aspect 5 is the phase change thermal interface material of any one of Aspect 1-4, further comprising at least one of: from about 84 wt. % to about 94 wt. % of thermally conductive filler; from about 0.1 wt. % to about 5.0 wt. % of phase change wax; from about 0.3 wt. % to about 2.0 wt. % of coupling agent; from about 5.0 wt. % to about 10.0 wt. % of polymer matrix material; and from about 0.05 wt. % to about 1.0 wt. % of at least one additive, based on the total weight of the phase change thermal interface material.

Aspect 6 is the phase change thermal interface material of any one of Aspect 1-5, further comprising at least one of: from about 78 vol. % to about 83 vol. % of thermally conductive filler; from about 0.25 vol. % to about 2.10 vol. % of phase change wax; from about 0.75 vol. % to about 2.10 vol. % of coupling agent; and from about 13 vol. % to about 18.2 vol. % of polymer matrix material, based on the total volume of the phase change thermal interface material.

Aspect 7 is the phase change thermal interface material of any one of Aspect 1-6, wherein the phase change wax comprises at least one of a paraffin and polymer wax.

Aspect 8 is the phase change thermal interface material of any one of Aspect 1-7, further comprising from about 0.05 wt. % to about 1.0 wt. % of at least one additive, the at least one additive comprising at least one of: a dispersant; a crosslinker; a catalyst; an inhibitor; a release agent; a pigment; and a coupling agent.

Aspect 9 is the phase change thermal interface material of any one of Aspect 1-8, wherein the polymer matrix material comprises hydrogenated polybutadiene.

Aspect 10 is the phase change thermal interface material of any one of Aspect 1-9, wherein the coupling agent comprises at least one of a silane coupling agent, a titanate coupling agent, an aluminate coupling agent, a zirconate coupling agent, and a stearic acid coupling agent.

Aspect 11 is the phase change thermal interface material of any one of Aspect 1-10, wherein the thermally conductive filler has an average particle size (D50) from about 1 μm to about 6 μm, as determined by dynamic light scattering ISO 13320-1.

Aspect 12 is an electronic component comprising: a heat sink; an electronic chip; and a phase change thermal interface material positioned between the heat sink and the electronic chip, wherein the phase change thermal interface material comprises: a thermally conductive filler, the thermally conductive filler comprising at least one of: from about 50 wt. % to about 70 wt. % aluminum powder; from about 19 wt. to about 30 wt. % aluminum oxide; and from about 1 wt. % to about 9 wt. % zinc oxide, based on the total weight of the phase change thermal interface material; a phase change wax; a coupling agent; and a polymer matrix material; wherein the phase change thermal interface material has a thermal impedance from about 0.02° C.cm²/W to about 0.04° C.cm²/W, as determined by ASTM D5470.

Aspect 13 is the electronic component of Aspect 12, wherein the thermally conductive filler further comprises from about 52 vol. % to 68 vol. % of aluminum powder; from about 12 vol. % to about 24 vol. % of aluminum oxide; and from about 0.5 vol. % to about 4 vol. % zinc oxide, based on the total volume of the phase change thermal interface material.

Aspect 14 is the electronic component of either Aspect 12 or Aspect 13, wherein the phase change thermal interface material has a thermal conductivity from about 3.5 W/m·K to about 5.5 W/m·K, as determined by ASTM D5470.

Aspect 15 is the electronic component of any one of Aspects 12-14, wherein the phase change thermal interface material has a bold line thickness from about 5 μm to about 15 μm.

Aspect 16 is the electronic component of any one of Aspects 12-15, wherein the phase change thermal interface material has a viscosity from about 500 Pa·s to about1800 Pa·s at 80° C.

Aspect 17 is the electronic component of any one of Aspects 12-16, wherein the phase change thermal interface material further comprises at least one of: from about 84 wt. % to about 94 wt. % of thermally conductive filler; from about 0.1 wt. % to about 5.0 wt. % of phase change wax; from about 0.3 wt. % to about 2.0 wt. % of coupling agent; and from about 5.0 wt. % to about 10.0 wt. % of polymer matrix material, based on the total weight of the phase change thermal interface material.

Aspect 18 is the electronic component of any one of Aspects 12-17, further comprising at least one of: from about 78 vol. % to about 83 vol. % of thermally conductive filler; from about 0.25 vol. % to about 2.10 vol. % of phase change wax; from about 0.75 vol. % to about 2.10 vol. % of coupling agent; and from about 13 vol. % to about 18.2 vol. % of polymer matrix material, based on the total volume of the phase change thermal interface material.

Aspect 19 is the electronic component of any one of Aspects 12-18, wherein the phase change wax comprises at least one of a paraffin and polymer wax.

Aspect 20 is the electronic component of any one of Aspects 12-19, further comprising from about 0.05 wt. % to about 1.0 wt. % of at least one additive, the at least one additive comprising at least one of: a dispersant; a crosslinker; a catalyst; an inhibitor; a release agent; a pigment; and a coupling agent.

Aspect 21 is the electronic component of any one of Aspects 12-20, wherein the polymer matrix material comprises a hydrogenated polybutadiene.

Aspect 22 is the electronic component of any one of Aspects 12-21, wherein the coupling agent comprises at least one of a silane coupling agent, a titanate coupling agent, an aluminate coupling agent, a zirconate coupling agent, and a stearic acid coupling agent.

Aspect 23 is the electronic component of any one of Aspects 12-22, wherein the thermally conductive filler has an average particle size (D50) from about 1 μm to about 6 μm, as determined by dynamic light scattering ISO 13320-1.

Aspect 24 is a method for applying a phase change thermal interface material to a substrate, comprising: combining each of a thermally conductive filler, a phase change wax, a coupling agent, and a polymer matrix material to form the phase change thermal interface material; wherein the thermally conductive filler comprises: from about 50 wt. % to about 70 wt. % aluminum powder; from about 19 wt. % to about 30 wt. % aluminum oxide; and from about 1 wt. % to about 9 wt. % zinc oxide, based on the total weight of the phase change thermal interface material; combining the phase change thermal interface material with a solvent to form a phase change thermal interface material paste; and applying the phase change thermal interface material to a metal substrate.

What is claimed is:

1. A phase change thermal interface material, comprising:
a thermally conductive filler;
wherein the thermally conductive filler comprises:
from about 50 wt. % to about 70 wt. % of aluminum powder;
from about 19 wt. % to about 30 wt. % of aluminum oxide; and
from about 1 wt. % to about 9 wt. % zinc oxide, based on the total weight of the phase change thermal interface material;
a phase change wax;
a coupling agent; and
a polymer matrix material;
wherein the phase change thermal interface material has a thermal impedance from about 0.02° C.cm²/W to about 0.04° C.cm²/W, as determined by ASTM D5470.

2. The phase change thermal interface material of claim 1, wherein the phase change thermal interface material has a thermal conductivity from about 3.5 W/m·K to about 5.5 W/m·K, as determined by ASTM D5470.

3. The phase change thermal interface material of claim 1, wherein the phase change thermal interface material has a viscosity from about 500 Pa·s to about 1800 Pa·s at 80° C.

4. The phase change thermal interface material of claim 1, further comprising at least one of:
from about 84 wt. % to about 94 wt. % of thermally conductive filler;
from about 0.1 wt. % to about 5.0 wt. % of phase change wax;
from about 0.3 wt. % to about 2.0 wt. % of coupling agent; and
from about 5.0 wt. % to about 10.0 wt. % of polymer matrix material, based on the total weight of the phase change thermal interface material.

5. The phase change thermal interface material of claim 1, wherein the phase change wax comprises at least one of a paraffin and polymer wax.

6. The phase change thermal interface material of claim 1, further comprising from about 0.05 wt. % to about 1.0 wt. % of at least one additive, the at least one additive comprising at least one of:
a dispersant;
a crosslinker;
a catalyst;
an inhibitor;
a release agent;
a pigment; and
a coupling agent.

7. The phase change thermal interface material of claim 1, wherein the polymer matrix material comprises hydrogenated polybutadiene.

8. The phase change thermal interface material of claim 6, wherein the coupling agent comprises at least one of a silane coupling agent, a titanate coupling agent, an aluminate coupling agent, a zirconate coupling agent, and a stearic acid coupling agent.

9. The phase change thermal interface material of claim 1, wherein the thermally conductive filler has an average particle size (D50) from about 1 μm to about 6 μm, as determined by dynamic light scattering ISO 13320-1.

10. An electronic component comprising:
a heat sink;
an electronic chip; and
a phase change thermal interface material positioned between the heat sink and the electronic chip, wherein the phase change thermal interface material comprises:
a thermally conductive filler, the thermally conductive filler comprising at least one of:
from about 50 wt. % to about 70 wt. % aluminum powder;
from about 19 wt. to about 30 wt. % aluminum oxide; and
from about 1 wt. % to about 9 wt. % zinc oxide, based on the total weight of the phase change thermal interface material;
a phase change wax;
a coupling agent; and
a polymer matrix material;
wherein the phase change thermal interface material has a thermal impedance from about 0.02° C.cm²/W to about 0.04° C.cm²/W, as determined by ASTM D5470.

11. The electronic component of claim 10, wherein the phase change thermal interface material has a thermal conductivity from about 3.5 W/m·K to about 5.5 W/m·K, as determined by ASTM D5470.

12. The electronic component of claim 10, wherein the phase change thermal interface material has a bold line thickness from about 5 μm to about 15 μm.

13. The electronic component of claim 10, wherein the phase change thermal interface material has a viscosity from about 500 Pa·s to about1800 Pa·s at 80° C.

14. The electronic component of claim 10, wherein the phase change thermal interface material further comprises at least one of:
from about 84 wt. % to about 94 wt. % of thermally conductive filler;
from about 0.1 wt. % to about 5.0 wt. % of phase change wax;
from about 0.3 wt. % to about 2.0 wt. % of coupling agent; and
from about 5.0 wt. % to about 10.0 wt. % of polymer matrix material, based on the total weight of the phase change thermal interface material.

15. The electronic component of claim 10, wherein the phase change wax comprises at least one of a paraffin and polymer wax.

16. The electronic component of claim 10, further comprising from about 0.05 wt. % to about 1.0 wt. % of at least one additive, the at least one additive comprising at least one of:
a dispersant;
a crosslinker;
a catalyst;
an inhibitor;
a release agent;
a pigment; and
a coupling agent.

17. The electronic component of claim 10, wherein the polymer matrix material comprises a hydrogenated polybutadiene.

18. The electronic component of claim 16, wherein the coupling agent comprises at least one of a silane coupling agent, a titanate coupling agent, an aluminate coupling agent, a zirconate coupling agent, and a stearic acid coupling agent.

19. The electronic component of claim 10, wherein the thermally conductive filler has an average particle size (D50) from about 1 μm to about 6 μm, as determined by dynamic light scattering ISO 13320-1.

20. A method for applying a phase change thermal interface material to a substrate, comprising:
combining each of a thermally conductive filler, a phase change wax, a coupling agent, and a polymer matrix material, to form the phase change thermal interface material;
wherein the thermally conductive filler comprises:
from about 50 wt. % to about 70 wt. % aluminum powder;
from about 19 wt. % to about 30 wt. % aluminum oxide; and
from about 1 wt. % to about 9 wt. % zinc oxide, based on the total weight of the phase change thermal interface material;
combining the phase change thermal interface material with a solvent to form a phase change thermal interface material paste; and
applying the phase change thermal interface material paste to a metal substrate.
